(19) United States
(12) Patent Application Publication
(10) Pub. No.: US 2008/0160421 A1
(43) Pub. Date: Jul. 3, 2008

(54) HOLOGRAM RECORDING MEDIUM

(75) Inventors: Naoki HAYASHIDA, Tokyo (JP); Atsuko Kosuda, Tokyo (JP); Jiro Yoshinari, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK Corporation, Tokyo (JP)

(21) Appl. No.: 11/964,464

(22) Filed: Dec. 26, 2007

(30) Foreign Application Priority Data
Dec. 28, 2006 (JP) 2006-354450

(51) Int. Cl. G03F 7/00

(52) U.S. Cl. 430/2

(57) ABSTRACT

The present invention provides a hologram recording medium which is suitable for volume hologram record and can attain high refractive index change, flexibility, high sensitivity, low scattering, environment resistance, durability, low dimensional change (low shrinkage) and high multiplicity in holographic memory record using not only a green laser but also a blue laser. A hologram recording medium (11) comprising at least a hologram recording layer (21), wherein the hologram recording layer contains a metal oxide matrix comprising metal oxide fine particles, and a photopolymerizable compound; the metal oxide fine particles comprise metal oxide fine particles containing Ti as a metallic element; and at the time of subjecting the hologram recording layer before exposure to light to an extraction operation in n-butyl alcohol having a mass 100 times the mass (W) of said recording layer, thereby yielding a sol solution; filtrating the sol solution to obtain a filtrated sol solution; and measuring particle diameter distribution of sol particles in the filtrated sol solution by a dynamic light scattering method; and obtaining an average particle diameter thereof, the average particle diameter of the sol particles is in the range of 5 nm or more and 50 nm or less.

### BACKGROUND OF THE INVENTION

1. Field of the Invention

The present invention relates to a hologram recording medium having a hologram recording layer suitable for volume hologram record. The present invention relates in particular to a hologram recording medium having a hologram recording layer suitable for record/reproduction using not only a green laser light but also a blue laser light.

2. Disclosure of the Related Art

Research and development of holographic memories have been advanced as large-capacity recording technique making high-speed transmission possible. O plus E, vol. 25, No. 4, 385-390 (2003) describes basic structures of holographic memories and a coming prospect thereof.

Examples of the property required for a hologram recording material include high refractive index change at the time of recording, high sensitivity, low scattering, environment resistance, durability, low dimensional change, and high multiplicity. About holographic memory record using a green laser, various reports have been made hitherto as follows.

As a hologram recording material, there is known a photopolymer material made mainly of an organic binder polymer and a photopolymerizable monomer. However, the photopolymer material has problems about environment resistance, durability and others. In order to solve the problems of the photopolymer material, attention has been paid to an organic-inorganic hybrid material made mainly of an inorganic matrix and a photopolymerizable monomer, and the hybrid material has been investigated. The inorganic matrix is excellent in environment resistance and durability.

For example, Japanese Patent No. 2953200 discloses a film for optical recording wherein a photopolymerizable monomer or oligomer and a photopolymerization initiator are contained in an inorganic substance network film. It is also disclosed that the brittleness of the inorganic network film is improved by modifying the inorganic network organically. However, the compatibility between the inorganic substance network and the photopolymerizable monomer or oligomer is bad. Therefore, a uniform film is not easily obtained. A specific disclosure of the publication is that a photosensitive layer having a thickness of about 10 μm (par. [0058]) is exposed to an argon laser having a wavelength of 514.5 nm (par. [0059]).

JP-A-2005-77740 discloses a hologram recording material comprising metal oxide particles, a polymerizable monomer and a photopolymerization initiator wherein the metal oxide particles are treated with a surface treating agent in which a hydrophobic group and a functional group which can undergo dehydration-condensation with a hydroxyl group on the surface of the metal oxide particles are bonded to a metal atom, and the metal atom is selected from the group consisting of titanium, aluminum, zirconium, and chromium. The publication discloses yin the paragraph [0075] that the metal oxide particles which are before surface treatment have a diameter of 1 to 100 nm. As regards record, a specific disclosure of the publication is that record was made in a hologram recording layer having a thickness of 50 μm (par. [0086]), using a YAG laser having a wavelength of 532 nm in Example 1 (par. [0089]).

JP-A-2005-99612 discloses a hologram recording material comprising a compound having one or more polymerizable functional groups, a photopolymerization initiator, and colloidal silica particles. The publication discloses in the claim 3 that the colloidal silica particles have an average diameter of 4 nm or more and 30 nm or less. As regards record, a specific disclosure of the publication is that record was made in a hologram recording layer having a thickness of 50 μm, using a Nd:YVO₄ laser having a wavelength of 532 nm (Example 1, par. [0036]).

JP-A-2005-321674 discloses a hologram recording material comprising: an organometallic compound at least containing at least two kinds of metals (Si and Ti), oxygen, and an aromatic group, and having an organometallic unit wherein two aromatic groups are directly bonded to one metal (Si); and a photopolymerizable compound. In Example 1 of the publication (in particular, pars. [0074] to [0078]), it is disclosed that a hologram recording medium which has a layer of the above-mentioned hologram recording material having a thickness of 100 μm gave a high transmittance, a high refractive index change, a low scattering, and a high multiplicity in record using a Nd:YAG laser (532 nm).

### SUMMARY OF THE INVENTION

Any of the above-mentioned publications disclose holographic memory record using a green laser, but do not disclose holographic memory record using a blue laser.

As the wavelength of a recording/reproducing laser is shorter, any hologram recording layer is required to have a higher mechanical strength, a higher flexibility and a higher homogeneity. If the mechanical strength of the hologram recording layer is insufficient, an increase in the shrinkage of the layer when recording is made or a fall in the storage reliability is caused. In particular, in order to obtain a sufficient contrast based on refractive index modulation by means of a recording/reproducing laser having a wavelength in the short wavelength region, it is preferred to make the microscopic mechanical strength high up to some degree, and restrain monomer-shift and dark reaction after the layer is exposed to light for recording. If the flexibility of the hologram recording layer is insufficient, the shift of the photopolymerizable monomer in the layer is hindered in recording so that the sensitivity falls. If the homogeneity is insufficient, scattering is caused at the time of recording/reproducing. Thus, the reliability of the recording/reproducing itself deteriorates. An effect of the scattering based on the insufficient homogeneity of the recording layer becomes remarkable more easily in the case of a recording/reproducing laser having a wavelength in the short wavelength region.

An object of the present invention is to provide a hologram recording medium which is suitable for volume hologram record and can attain high refractive index change, flexibility, high sensitivity, low scattering, environment resistance, durability, low dimensional change (low shrinkage) and high multiplicity in holographic memory record using not only a green laser but also a blue laser.

The present inventors have made investigations, so as to find out that when a blue laser is used to make a holographic memory record in the hologram recording medium disclosed in JP-A-2005-321674, the light transmittance thereof falls so that good holographic memory recording characteristics cannot be obtained. When a light transmittance falls, holograms (interference fringes) are unevenly formed in the recording layer along the thickness direction of the recording layer so that scattering-based noises and the like are generated. It has been found out that in order to obtain good hologram image characteristics, it is necessary that the medium has a light transmittance of 50% or more.

A light transmittance of a hologram recording layer depends on a thickness thereof. As the thickness of the recording layer is made smaller, the light transmittance is improved; however, the widths of diffraction peaks obtained when reproducing light is irradiated into a recorded pattern become larger so that separability between adjacent diffraction peaks deteriorates. Accordingly, in order to obtain a sufficient SN ratio (Signal to Noise ratio), it is indispensable to make a shift interval (an angle or the like) large when multiple record is made. For this reason, a high multiplicity cannot be attained. In the use of a hologram recording medium in any recording system, the thickness of its recording layer is required to be at lowest 100 μm in order to attain holographic memory recording characteristics for ensuring a high multiplicity.

Furthermore, the present inventors have made eager investigations to find out that in order for a medium as described above to have a light transmittance of 50% or more and have a hologram recording layer of at least 100 μm thickness while said recording layer satisfies a high mechanical strength, a high flexibility and a high homogeneity, the particle diameter of metal oxide fine particles present in the hologram recording layer should be set into the range of 5 nm or more and 50 nm or less before the layer is exposed to light for recording.

The present invention includes the followings:

(1) A hologram recording medium comprising at least a hologram recording layer,

wherein the hologram recording layer contains a metal oxide matrix comprising metal oxide fine particles, and a photopolymerizable compound, the metal oxide fine particles comprise metal oxide fine particles containing Ti as a metallic element, and

at the time of subjecting the hologram recording layer before exposure to light for recording to an extraction operation in n-butyl alcohol having a mass 100 times the mass (W) of said recording layer under the following conditions:

ultrasonic vibration at 25° C. for 1 hour followed by stirring at 25° C. for 9 hours,

thereby yielding a sol solution;

filtrating the sol solution two times through syringe filters having a pore diameter of 0.45 μm;

measuring particle diameter distribution of sol particles in the filtrated sol solution by a dynamic light scattering method; and obtaining an average particle diameter thereof, the average particle diameter of the sol particles is in the range of 5 nm or more and 50 nm or less.

(2) The hologram recording medium according to the above-described (1), wherein a dry mass (W_{D}) of the filtrated sol solution is 80% or more of the mass (W) of the recording layer before the extraction operation.

(3) The hologram recording medium according to the above-described (1) or (2), wherein the metal oxide matrix is a matrix prepared from a titanium compound having at least one hydrolyzable group.

(4) The hologram recording medium according to the above-described (1) or (2), wherein the metal oxide matrix is a matrix prepared from a titanium compound having at least one hydrolyzable group and a silicon compound having at least one hydrolyzable group.

(5) The hologram recording medium according to any one of the above-described (1) to (4), further comprising a photopolymerization initiator.

(6) The hologram recording medium according to any one of the above-described (1) to (5), wherein the hologram recording layer has a thickness of at least 100 μm.

(7) The hologram recording medium according to any one of the above-described (1) to (6), wherein said hologram recording medium has a light transmittance is 50% or more at a wavelength of 405 nm, or a light reflectance is 25% or more at a wavelength of 405 nm.

(8) The hologram recording medium according to any one of the above-described (1) to (7), wherein record/reproduction of said hologram recording medium are made using a laser light having a wavelength of 350 to 450 nm.

In the hologram recording medium of the present invention, the particle diameter of the metal oxide fine particles present in the hologram recording layer before the layer is exposed to light is set into the range of 5 nm or more and 50 nm or less; therefore, while the medium has a light transmittance of 50% or more and has a hologram recording layer of at least 100 μm thickness, this hologram recording layer satisfies a high mechanical strength, a high flexibility and a high homogeneity. According to the hologram recording medium of the present invention, therefore, a good holographic memory recording property can be obtained without lowering the light transmittance in recording/reproducing through a blue laser ray as well as in recording/reproducing through a green laser ray.

### BRIEF DESCRIPTION OF THE DRAWINGS

FIG. 1 is a view illustrating a schematic cross section of a hologram recording medium produced in the example.

FIG. 2 is a plane view illustrating the outline of a hologram recording optical system used in the example.

### DETAILED DESCRIPTION OF THE INVENTION

The hologram recording medium of the present invention comprises at least a hologram recording layer (namely, a hologram recording material layer) described later. Usually, a hologram recording medium comprises a supporting substrate (i.e., a substrate) and a hologram recording layer; however, a hologram recording medium may be made only of a hologram recording layer without having any supporting substrate. For example, a medium composed only of a hologram recording layer may be obtained by forming the hologram recording layer onto the substrate by application, and then peeling the hologram recording layer off from the substrate. In this case, the hologram recording layer is, for example, a layer having a thickness in the order of millimeters.

The hologram recording layer contains a metal oxide matrix comprising metal oxide fine particles, and a photopolymerizable compound. The metal oxide fine particles comprise metal oxide fine particles containing Ti as a metallic element. The oxide fine particles containing Ti are titania (TiO₂) fine particles which may have an organic group appropriately, or Ti-containing complex oxide fine particles which may have an organic group appropriately. The Ti-containing complex oxide fine particles are not particularly limited, and are, for example, fine particles made of TiMOx wherein M=Si, Fe, Sn, Sb, Zr or the like. The Ti-containing complex oxide fine particles are in particular preferably Ti/Si complex oxide fine particles which may have an organic group appropriately. Moreover, the metal oxide fine particles preferably comprise silica (SiO₂) fine particles which may have an organic group appropriately, or Si-containing complex oxide fine particles which may have an organic group appropriately. Besides these particles, alumina, zirconia or other fine particles may be contained in the metal oxide fine particles. As described above, the metal oxide fine particles contain Ti as a metallic element and preferably contain Si. The particles may contain any optional metal other than Ti and Si (such as Ta, Al, Zn, In, Fe, Sn, Sb or Zr). In the case that the metal oxide fine particles which constitute the metal oxide matrix contain two or more species of metals as constituting elements, the refractive index and other characteristics are easily controlled. Thus, the case is preferred for the design of the recording material.

The metal oxide fine particles which constitute the metal oxide matrix are particles obtained by causing the following compound(s) to undergo hydrolysis and polymerization reaction (the so-called sol-gel reaction), thereby converting the compound(s) into a metal oxide fine particle form: one or more corresponding titanium compound(s) each having at least one hydrolyzable group (such as alkoxide compounds or chlorides of titanium); and preferably, a silicon compound having at least one hydrolyzable group (such as an alkoxide compound or chloride of silicon); and optionally, a compound of a metal other than titanium and silicon, said compound having at least one hydrolyzable group (such as an alkoxide compound or chloride of a metal other than titanium and silicon). The metal oxide matrix containing the metal oxide fine particles is in a gel or sol form. The metal oxide matrix functions as a matrix or a dispersing medium for the photopolymerizable compound in the hologram recording layer. In other words, the photopolymerizable compound in a liquid phase is evenly dispersed with good compatibility in the gel- or sol-form metal oxide matrix.

When light having coherency is irradiated onto the hologram recording layer, the photopolymerizable organic compound (monomer) undergoes polymerization reaction in the exposed portion so as to be polymerized, and further the photopolymerizable organic compound diffuses and shifts from the unexposed portion into the exposed portion so that the polymerization of the exposed portion further advances. As a result, an area where the polymer produced from the photopolymerizable organic compound is large in amount and an area where the polymer is small in amount are formed in accordance with the intensity distribution of the light. At this time, the metal oxide shifts from the area where the polymer is large in amount to the area where the polymer is small in amount, so that the area where the polymer is large in amount becomes an area where the metal oxide is small in amount and the area where the polymer is small in amount becomes an area where the metal oxide is large in amount. In this way, the light exposure causes the formation of the area where the polymer is large in amount and the area where the metal oxide is large in amount. When a refractive index difference exists between the polymer and the metal oxide, a refractive index change is recorded in accordance with the light intensity distribution.

In order to obtain a better recording property in the hologram recording material, it is necessary that a difference is large between the refractive index of the polymer produced from the photopolymerizable compound and that of the metal oxide. The refractive indexes of the polymer and the metal oxide may be designed so as to make any one of the refractive indexes high (or low).

In the present invention, the metal oxide contains Ti as the essential constituent element thereof; therefore, a high refractive index of the metal oxide can be obtained. Accordingly, it is advisable to design the hologram recording material to cause the metal oxide to have a high refractive index and cause the polymer to have a low refractive index.

Ti is a preferred constituent element of the metal oxide from the viewpoint that Ti can realize a high refractive index. On the other hand, Ti atom-containing metal oxide has a drawback that said metal oxide easily absorbs light having a wavelength in the blue wavelength region. Specifically, when the metal oxide absorbs light having a wavelength in the blue wavelength region, the light transmittance of a hologram recording medium using such a hologram recording layer lowers in holographic memory record using a blue laser.

The present inventors have investigated the particle diameter of the metal oxide fine particles which constitute the metal oxide matrix in the hologram recording layer in hologram recording media. The present inventors have then found out that a hologram recording medium can have a light transmittance of 50% or more and a hologram recording layer of at least 100 μm thickness while said recording layer can satisfy a high mechanical strength, a high flexibility and a high homogeneity in the case that at the time of subjecting the hologram recording layer before exposure to light for recording to an extraction operation in n-butyl alcohol having a mass 100 times the mass (W) of said recording layer under the following conditions:

ultrasonic vibration at 25° C. for 1 hour followed by stirring at 25° C. for 9 hours,

thereby yielding a sol solution;

filtrating the sol solution two times through syringe filters having a pore diameter of 0.45 μm;

measuring particle diameter distribution of sol particles in the filtrated sol solution by a dynamic light scattering method; and obtaining an average particle diameter thereof, the average particle diameter of the sol particles is in the range of 5 nm or more and 50 nm or less.

From the hologram recording medium before said medium is exposed to light for recording, an arbitrary amount [mass (W)] of the hologram recording layer is scratched away. To the scratched hologram recording material [mass (W)] is added n-butyl alcohol having a mass of 100 W. The hologram recording material in n-butyl alcohol is subjected to an extraction operation of ultrasonic vibration at 25° C. for 1 hour followed by stirring at 25° C. for 9 hours, thereby yielding a sol solution. The yielded sol solution is filtrated two times through syringe filters having a pore diameter of 0.45 μm [membrane filters made of hydrophilic PTFE (polytetrafluoroethylene), specifically, disposable filter units 25HP045AN made of hydrophilic PTFE, manufactured by Toyo Roshi Kaisha, Ltd.; pore diameter: 0.45 μm], so as to yield a filtrated sol solution. In each of the two filtration operations, each of the syringe filters used is a virgin syringe filter. The resultant is used as a dynamic light scattering measuring sample. The sample is subjected to dynamic light scattering measurement so as to measure a particle diameter distribution of the sol particles. An average particle diameter of the sol particles is then obtained in the usual way.

It appears that the average particle diameter obtained by this method sufficiently reflects the particle diameter of the metal oxide fine particles which constitute the metal oxide matrix in the hologram recording layer in the hologram recording medium. In connection with this, attention should be paid to a matter that even if metal oxide sol particles having certain particle diameters are used in sol-gel reaction for forming the metal oxide matrix material of the hologram recording layer, the particle diameters of the sol particles are not necessarily consistent with the particle diameters of the metal oxide fine particles in the hologram recording layer. The sol particles grow when the metal oxide matrix material is prepared, and further the particles also grow when the particles are applied onto a substrate and then dried.

In the present invention, the average particle diameter of the sol particles ranges from 5 nm or more and 50 nm or less. If the average particle diameter is less than 5 nm, the mechanical strength of the metal oxide matrix made of the particles is insufficient. Thus, the shrinkage of the recording layer increases when recording is made or the storage reliability of the recording layer deteriorates. On the other hand, if the average particle diameter is more than 50 nm, the dispersibility of the particles in the metal oxide matrix made of the particles is not homogeneous so that the particles aggregate easily or the recording layer gets clouded. If the homogeneity of the recording layer is insufficient, scattering is caused at the time of recording/reproducing so that the reliability of the recording/reproducing itself deteriorates. If the average particle diameter is more than 50 nm, the flexibility of the metal oxide matrix made of the particles is insufficient. Thus, the shift of the photopolymerizable monomer is hindered at the time of recording, so that the sensitivity falls. The average particle diameter of the sol particles is preferably 7 nm or more and 50 nm or less, more preferably 7 nm or more and 35 nm or less, even more preferably 10 nm or more and 35 nm or less.

In connection with the above-mentioned extraction and filtration operation conditions, it is preferred that the dry mass (W_{D}) of the filtrated sol solution is 80% or more of the mass (W) of the recording layer before the extraction operation (that is, W_{D}≧0.8 W). If the dry mass (W_{D}) of the filtrated sol solution is less than 80% of the mass (W) of the recording layer before the extraction operation, it means that insoluble matters remaining without being extracted from the scratched recording layer under the extraction operation conditions are present at a mass of 20% or more of the mass (W) of the recording layer before the extraction operation. If the amount of the insoluble matters is large in such a manner, the obtained average particle diameter of the extracted and filtrated sol particles may not reflect actual particle diameters of the metal oxide fine particles which constitute the metal oxide matrix in the hologram recording layer even if the obtained average particle diameter is in the range of 5 nm or more and 50 nm or less. The dry mass (W_{D}) of the filtrated sol solution can be obtained by drying the filtrated sol solution and then weighing the resultant. This dry mass (W_{D}) includes masses of the photopolymerizable compound, the photopolymerization initiator, and others that are extracted into n-butyl alcohol besides the mass of the metal oxide fine particles.

In the present invention, the metal oxide matrix is composed of the metal oxide fine particles having the above-mentioned specified average particle diameter. As described above, the metal oxide matrix can be obtained by causing one or more corresponding hydrolyzable group-containing titanium compound(s), a preferably-used hydrolyzable group-containing silicon compound, and an optionally-used hydrolyzable group-containing compound of a metal other than titanium and silicon to undergo hydrolysis and polymerization reaction (the so-called sol-gel reaction), thereby converting the compound(s) into a metal oxide fine particle form.

In the present invention, it is preferred that the metal oxide fine particles contain an organic group in order that the metal oxide matrix has improved flexibility and compatibility with the photopolymerizable compound. For example, it is preferred that metal atoms in an amount of 20 atomic % or more, preferably 30 atomic % or more of all the metal atoms contained in the metal oxide matrix each have at least one aromatic hydrocarbon group as an organic group. The aromatic hydrocarbon group may be bonded directly to each of the metal atoms or may be bonded through a linking group (for example, a non-aromatic hydrocarbon moiety such as an alkylene group) to each of the metal atoms. Alternatively, the aromatic hydrocarbon group may be bonded, as an organic ligand or a part of an organic ligand, to each of the metal atoms through a coordinate bond.

In order to obtain such organic group-containing metal oxide fine particles, it is preferred to use a hydrolyzable group-containing organosilicon compound from the viewpoint of availability and reactivity of the hydrolyzable group-containing organometallic compound as a starting material.

The hydrolyzable group-containing organosilicon compound as a starting material may be a compound wherein an aromatic hydrocarbon group is bonded directly to a silicon atom, examples of which include triphenylethoxysilane, diphenyldimethoxysilane, diphenyldiethoxysialne, phenyltrimethoxysilane, phenyltriethoxysilane, di(p-tolyl)dimethoxysilane, and p-tolyltrimethoxysilane.

Examples of the above-mentioned organosilicon compound wherein an aromatic hydrocarbon group is bonded through a non-aromatic hydrocarbon moiety to a silicon atom include (3-phenylpropyl)methyldichlorosilane, and [(chloromethyl)phenylpropyl]methyldimethoxysilane.

Examples of the above-mentioned organic ligand having an aromatic hydrocarbon group include benzyl acetoacetate, ethyl-2-[4-(pentyloxy)benzoyl]acetate, o-toluic acid, m-toluic cid, and m-anisic acid.

Of course, in the present invention, it is allowable to use a hydrolyzable group-containing silicon compound which contains no aromatic hydrocarbon group as a starting material besides an aromatic hydrocarbon group-containing organosilicon compound as described above. Examples of the silicon compound include tetramethoxysilane, tetraethoxysilane, tetrapropoxysilane, methyltrimethoxysilane, ethyltrimethoxysilane, propyltrimethoxysilane, methyltriethoxysilane, ethyltriethoxysialne, propyltriethoxysilane, γ-mercaptopropyltrimethoxysilane, γ-mercaptopropyltriethoxysilane, γ-aminopropyltrimethoxysilane, γ-aminopropyltriethoxysilane, dimethyldimethoxysilane, dimethyldiethoxysilane.

When a monoalkoxysilane such as triphenyethoxysilane and trimethylmethoxysilane is present, the polymerization reaction is stopped. Accordingly, the monoalkoxysilane can be used to adjust a molecular weight.

In the present invention, in order to set the particle diameter of the metal oxide fine particles which constitute the metal oxide matrix into the above-mentioned specified range of the average particle diameter, it is preferred to use, as the hydrolyzable group-containing organosilicon starting material, an alkoxysilane wherein one or more aromatic hydrocarbon group(s) is/are bonded directly to a silicon atom. The reactivity of the alkoxysilane is appropriately restrained by steric effect and electronic inductive effect of the aromatic hydrocarbon group(s), so that the hydrolysis and polycondensation reaction can be moderately advanced. It therefore becomes easy to set the average particle diameter of the metal oxide fine particles into the specified range.

The hydrolyzable group-containing titanium compound is not particularly limited, and examples thereof include titanium alkoxide compounds such as tetrapropoxytitanium, tetrabutoxytitanium, and a titanium butoxide oligomer (corresponding to a partially condensed hydrolysate of tetrabutoxytitanium).

The hydrolyzable group-containing compound of a metal other than titanium and silicon is not particularly limited, and examples thereof include pentaethoxytantalum [Ta(OEt)₅], tetraethoxytantalum pentanedionate [Ta(OEt)₄(C₅H₇O₂)], tetra-t-butoxyzirconium [Zr(O-tBu)₄], tetra-n-butoxyzirconium [Zr(O-nBu)₄], zirconium tetraacetylacetonate [Zr(C₅H₇O₂)₄], and other alkoxide compounds and diketonate compounds. Besides these compounds, metal alkoxide compounds; metal diketonate compounds; and metal acylate compounds can also be used.

In the present invention, a titanium material containing an aromatic hydrocarbon group or a different metal material containing an aromatic hydrocarbon group may be used besides a silicon material as described above.

In the present invention, in order to set the particle diameter of the metal oxide fine particles which constitute the metal oxide matrix into the above-mentioned specified range of the average particle diameter, it is preferred to use, as a starting material of a hydrolyzable group-containing compound of a metal other than silicon, an oligomer of a metal alkoxide (a condensed hydrolysate of a mononuclear metal alkoxide, preferably a trimer to a 20-mer thereof in connection with the average polymerization degree), and/or a compound having a chelate ligand the number of which is at least 0.5 per metal atom. The use of such a metal compound causes an appropriate restraint of the hydrolysis and polycondensation reaction rate to make it easy to set the average particle diameter of the metal oxide fine particles in the specified range.

The blend amounts of the hydrolyzable group-containing titanium compound and the hydrolyzable group-containing silicon compound are appropriately determined, considering the blend ratio between Ti and Si in the metal oxide matrix so as to give a desired refractive index. For example, it is advisable to set the atomic ratio of Ti/Si into the range of 0.1/1.0 to 10/1.0.

At the time of conducting sol-gel reaction of one or more metal alkoxide compound(s) containing a titanium alkoxide compound, it is preferred to use, as an organic solvent, an organic solvent which neither contains any cyclic ether skeleton nor any carbonyl oxygen. The present inventors have understood from their investigations that the absorption of blue light into the metal oxide matrix is caused not only by the organic group(s) contained in the metal oxide(s) but also by a complex of Ti (or coordination to Ti) formed between Ti and the organic solvent used in the sol-gel reaction. Accordingly, by using, as the organic solvent in the sol-gel reaction, an organic solvent which neither contains any cyclic ether skeleton nor any carbonyl oxygen, the absorption of blue light into the resultant metal oxide matrix can be decreased.

Ether oxygen in any cyclic ether skeleton and carbonyl oxygen are each high in capability of coordinating to Ti. Accordingly, it should be avoided to use, as the organic solvent in the sol-gel reaction, dioxane, tetrahydrofuran, N-methylpyrrolidone, N,N-dimethylformamide, N,N-dimethylacetamide, acetylacetone and the like. However, it is allowable that carbonyl oxygen or a cyclic ether which can never coordinate to a Ti atom, for example, in an acetylacetone molecule which is beforehand coordinated to a metal atom other than Ti so as to be stabilized, is contained in the starting composition subjected to the sol-gel reaction.

Preferred examples of the organic solvent include monoalcohol, dialcohol, and monoalkyl ether of dialcohol. Specific examples thereof include monoalcohols such as methanol, ethanol, propanol, isopropanol, and butanol; dialcohols such as ethylene glycol, and propylene glycol; and monoalkyl ethers of dialcohols such as 1-methoxy-2-propanol, and ethylene glycol monomethyl ether (methyl cellosolve). Out of these, the solvent to be used may be appropriately selected. Alternatively, a mixed solvent of these solvents may be used, and water may be added thereto. These solvents are low in capability of coordinating to Ti. Alternatively, even if the solvents coordinate to Ti, no transition absorption band at a low energy level is generated. Accordingly, even if these solvents remain in the metal oxide, the absorption of blue light into the resultant metal oxide is decreased.

The metal oxide matrix may contain trace amounts of elements other than the above.

In the present invention, the photopolymerizable compound is a photopolymerizable monomer. As the photopolymerizable compound, a radical polymerizable compound is preferred.

The radical polymerizable compound is not particularly limited as long as the compound has in the molecule one or more radical polymerizable unsaturated double bonds. For example, a monofunctional and multifunctional compound having a (meth)acryloyl group or a vinyl group can be used. The wording “(meth)acryloyl group” is a wording for expressing a methacryloyl group and an acryloyl group collectively.

Examples of the compound having a (meth)acryloyl group, out of the radical polymerizable compounds, include monofunctional (meth)acrylates such as phenoxyethyl(meth)acrylate, 2-methoxyethyl(meth)acrylate, 2-hydroxyethyl(meth)acrylate, benzyl(meth)acrylate, cyclohexyl(meth)acrylate, ethoxydiethylene glycol(meth)acrylate, methoxypolyethylene glycol(meth)acrylate, methyl(meth)acrylate, polyethylene glycol(meth)acrylate, polypropylene glycol(meth)acrylate, and stearyl(meth)acrylate; and

polyfunctional (meth)acrylates such as trimethylolpropane tri(meth)acrylate, pentaerythritol tetra(meth)acrylate, dipentaerythritol hexa(meth)acrylate, diethylene glycol di(meth)acrylate, triethylene glycol di(meth)acrylate, tetraethylene glycol di(meth)acrylate, polyethylene glycol di(meth)acrylate, bis(2-hydroxyethyl)isocyanurate di(meth)acrylate, and 2,2-bis[4-(acryloxy-diethoxy)phenyl]propane. However, the compound having a (meth)acryloyl group is not necessarily limited thereto.

Examples of the compound having a vinyl group include monofunctional vinyl compounds such as styrene, and ethylene glycol monovinyl ether; and polyfunctional vinyl compounds such as divinylbenzene, ethylene glycol divinyl ether, diethylene glycol divinyl ether, and triethylene glycol divinyl ether. However, the compound having a vinyl group is not necessarily limited thereto.

One kind of the radical polymerizable compound may be used, and two or more kinds thereof are used together. In the case of making the refractive index of the metal oxide high and making the refractive index of the organic polymer low, in the present invention, a compound having no aromatic group to have low refractive index (for example, refractive index of 1.5 or less) is preferred out of the above-mentioned radical polymerizable compounds. In order to make the compatibility with the metal oxide better, preferred is a more hydrophilic glycol derivative such as polyethylene glycol(meth)acrylate and polyethylene glycol di(meth)acrylate.

It is advisable that in the present invention the photopolymerizable compound is used, for example, in an amount of about 5 to 1,000% by weight of total (as a nonvolatile component) of the metal oxide matrix, preferably in an amount of 10 to 300% by weight thereof. If the amount of the photopolymerizable compound is less than 5% by weight, a large refractive index change is not easily obtained at the time of recording. If the amount of the photopolymerizable compound is more than 1,000% by weight, a large refractive index change is not easily obtained, either, at the time of recording. If the amount of the photopolymerizable compound is less than 5% by weight, the metal oxide concentration in the hologram recording material becomes too high after the solvent is volatilized. Thus, the average particle diameter of the metal oxide fine particles is not easily controlled into the above-mentioned specified range.

In the present invention, the hologram recording material further contains a photopolymerization initiator corresponding to the wavelength of recording light. When the photopolymerization initiator is contained in the hologram recording material, the polymerization of the photopolymerizable compound is promoted by the light exposure at the time of recording. Consequently, a higher sensitivity is achieved.

When a radical polymerizable compound is used as the photopolymerizable compound, a photo radical initiator is used. Examples of the photo radical initiator include Darocure 1173, Irgacure 784, Irgacure 651, Irgacure 184 and Irgacure 907 (each manufactured by Ciba Specialty Chemicals Inc.). The content of the photo radical initiator is, for example, about 0.1 to 10% by weight, preferably about 0.5 to 5% by weight on the basis of the radical polymerizable compound.

The hologram recording material composition may contain a dye that functions as a photosensitizer corresponding to the wavelength of recording light or the like besides the photopolymerization initiator. Examples of the photosensitizer include thioxanthones such as thioxanthen-9-one, and 2,4-diethyl-9H-thioxanthen-9-one; xanthenes; cyanines; melocyanines; thiazines; acridines; anthraquinones; and squaliriums. It is advisable to set an amount to be used of the photosensitizer into the range of about 5 to about 50% by weight of the radical photoinitiator, for example, about 10% by weight thereof.

A process for producing the hologram recording material will be described in the following.

The metal oxide matrix may be prepared by causing a hydrolyzable group-containing titanium compound (such as an alkoxide compound or chloride of titanium), a preferably-used hydrolyzable group-containing silicon compound (such as an alkoxide compound or chloride of silicon), and an optionally-used hydrolyzable group-containing compound of a metal other than titanium and silicon (such as an alkoxide or chloride of the metal other than titanium and silicon) to undergo hydrolysis and polymerization reaction (the so-called sol-gel reaction), thereby converting the compound(s) into a metal oxide fine particle form.

The hydrolysis and polymerization reaction of the hydrolyzable group-containing metal compound starting material(s) may be carried out by the same operation under the same conditions as in known sol-gel methods. For example, the reaction may be conducted by dissolving predetermined metal alkoxide compound starting material(s) into a preferred organic solvent as described above to prepare a homogenous solution, adding an appropriate acid catalyst dropwise to the solution, and stirring the solution in the presence of water. The amount of the solvent may be decided to set the concentration of the hydrolyzable group-containing metal compound starting material(s) in the whole of the solution to 90% by mass or less, preferably to 80% by mass or less. If the concentration is more than 90% by mass, the average particle diameter of the generated metal oxide fine particles is not easily controlled into the above-mentioned specified range because of the high concentration. The lower limit of the concentration is not particularly limited, and it is advisable to set to the lower limit to, for example, 15% by mass, preferably 20% by mass since the work efficiency of the application/drying of the solution onto a substrate for forming a recording material film falls if the concentration is too low.

Examples of the acid catalyst include: inorganic acids such as hydrochloric acid, sulfuric acid, nitric acid and phosphoric acid; organic acids such as formic acid, acetic acid, trichloroacetic acid, trifluoroacetic acid, propionic acid, methanesulfonic acid, ethanesulfonic acid, and p-toluenesulfonic acid; and the like.

The hydrolysis and polymerization reaction, which depends on the reactivity of the hydrolyzable group-containing metal compound starting material(s), may be conducted, in general, at room temperature (about 20 to 30° C.) for 0.5 hour or more and 5 hours or less, preferably 0.5 hour or more and 3 hours or less. There action maybe conducted in the atmosphere of an inert gas such as a nitrogen gas, or may be conducted under a reduced pressure of about 0.5 to 1 atm while an alcohol generated by the polymerization reaction is removed.

Before, during or after the hydrolysis, the photopolymerizable organic compound is mixed. The photopolymerizable organic compound may be mixed with the metal alkoxide compounds as the starting materials after, during or before the hydrolysis. In the case of the mixing after the hydrolysis, it is preferred to add and mix the photopolymerizable organic compound in the state that the sol-gel reaction system containing the metal oxide and/or the metal oxide precursor is sol in order to perform the mixing uniformly. The mixing of a photopolymerization initiator or photosensitizer can also be conducted before, during or after the hydrolysis.

The polycondensation reaction of the metal oxide precursor, with which the photopolymerizable compound is mixed, is advanced to yield a hologram recording material liquid wherein the photopolymerizable compound is uniformly incorporated in a metal oxide matrix in a sol-form. The hologram recording material liquid is applied onto a substrate, and then drying of the solvent and a sol-gel reaction are further advanced, thereby yielding a hologram recording material layer in a film form. In such a way, the hologram recording material layer is produced wherein the photopolymerizable compound is uniformly contained in a metal oxide matrix.

In the present invention, factors to control the average particle diameter of the metal oxide fine particles which constitute the metal oxide matrix are as follows:

### (1) Sol-Gel Reactivity of the Hydrolyzable Group-Containing Silicon:

Silicon alkoxide is generally smaller in hydrolysis and polycondensation reaction rate than alkoxide of a metal other than silicon. However, if the hydrolysis and polycondensation reaction rate of silicon alkoxide is large, the grain growth is promoted and further the particles aggregate easily in the reaction so that the particle diameter becomes large. Moreover, the reaction is not homogeneous. It is therefore preferred to restrain the hydrolysis and polycondensation reaction rate of the silicon alkoxide to some degree to advance the reaction moderately. For this purpose, for example, as described above, it is preferred to use, as the hydrolyzable group-containing silicon, an alkoxysilane wherein one or more aromatic hydrocarbon group(s) is/are bonded directly to a silicon atom. The reactivity of the alkoxysilane is appropriately restrained by steric effect and electronic inductive effect of the aromatic hydrocarbon group(s).

(2) Sol-Gel Reactivity of the Hydrolyzable Group-Containing Metal Compound(s) of Metal(s) other than Silicon:

Alkoxide of any metal (such as titanium) other than silicon is generally larger in hydrolysis and polycondensation reaction rate than silicon alkoxide. For this reason, the grain growth is rapid, and the particles aggregate easily during the reaction so that the particle diameter becomes large. Moreover, the reaction is not homogeneous. It is therefore preferred to restrain the hydrolysis and polycondensation reaction rate of titanium alkoxide appropriately. For this purpose, for example, as described above, it is preferred to use an oligomer of a metal alkoxide, and/or a metal compound having a chelate ligand.

### (3) Concentration of the Hydrolyzable Group-Containing Metal Compound(s) in the Sol-Gel Reaction:

If the concentration of the hydrolyzable group-containing metal compound(s) in the sol-gel reaction is high, the produced metal oxide fine particles bond to each other (aggregate) easily so that the particle diameter becomes large. As described above, therefore, it is preferred to adjust the amount of the used solvent to set the concentration of the hydrolyzable group-containing metal compound starting material(s) in the whole of the solution to 90% by mass or less, preferably 80% by mass or less.

### (4) Temperature and Time of the Sol-Gel Reaction:

As described above, it is advisable to conduct the hydrolysis and polymerization reaction generally at room temperature (about 20 to 30° C.) for 0.5 hour or more and 5 hours or less, preferably 0.5 hour or more and 3 hours or less provided that these conditions depend on the reactivity of the hydrolyzable group-containing metal compound starting material(s). A high reaction temperature causes the reaction to be promoted to make the grain growth rapid, and further causes the particles to aggregate during the reaction to make the particle diameter large. Moreover, the reaction is not homogeneous. The reaction over a time longer than required promotes the grain growth.

### (5) Concentration of the Photopolymerizable Monomer:

If the metal oxide concentration in the hologram recording material is too high after the solvent is volatilized, the generated metal oxide fine particles bond to each other (aggregate) easily so that the particle diameter becomes large. As described above, therefore, it is advisable to set the concentration of the photopolymerizable compound into the range of, for example, about 5 to 1,000% by weight of the whole (nonvolatile matters) of the metal oxide matrix.

In the present invention, metal oxide fine particles having an average particle diameter specified into the range of 5 nm or more and 50 nm or less can be obtained, considering the above-mentioned factors of controlling the average particle diameter of the metal oxide fine particles.

The hologram recording medium of the present invention is suitable for record and reproduction using not only a green laser light but also a blue laser light having a wavelength of 350 to 450 nm. When the reproduction is made using transmitted light, the medium preferably has a light transmittance of 50% or more at a wavelength of 405 nm. When the reproduction is made using reflected light, the medium preferably has a light reflectance of 25% or more at a wavelength of 405 nm.

The hologram recording medium is either of a medium having a structure for performing reproduction using transmitted light (hereinafter referred to as a transmitted light reproducing type medium), and a medium having a structure for performing reproduction using reflected light (hereinafter referred to as a reflected light reproducing type medium) in accordance with an optical system used for the medium.

The transmitted light reproducing type medium is constructed in such a manner that a laser light for readout is irradiated into the medium, the laser light irradiated therein is diffracted by signals recorded in its hologram recording material layer, and the laser light transmitted through the medium is converted to electric signals by means of an image sensor. In other words, in the transmitted light reproducing type medium, the laser light to be detected is transmitted through the medium toward the medium side opposite to the medium side into which the reproducing laser light is irradiated. The transmitted light reproducing type medium usually has a structure wherein its recording material layer is sandwiched between two supporting substrates. In an optical system used for the medium, the image sensor, for detecting the transmitted laser light, is set up in the medium side opposite to the medium side into which the reproducing laser light emitted from a light source is irradiated.

Accordingly, in the transmitted light reproducing type medium, the supporting substrate, the recording material layer, and any other optional layer(s) are each made of a light-transmitting material. It is unallowable that any element blocking the transmission of the reproducing laser light is substantially present. The supporting substrate is usually a rigid substrate made of glass or resin.

In the meantime, the reflected light reproducing type medium is constructed in such a manner that a laser light for readout is irradiated into the medium, the laser light irradiated therein is diffracted by signals recorded in its hologram recording material layer, and then, the laser light is reflected on its reflective film, and the reflected laser light is converted to electric signals by means of an image sensor. In other words, in the reflected light reproducing type medium, the laser light to be detected is reflected toward the same medium side as the medium side into which the reproducing laser light is irradiated. The reflected light reproducing type medium usually has a structure wherein the recording material layer is formed on a supporting substrate positioned at the medium side into which the reproducing laser light is irradiated; and a reflective film and an another supporting substrate are formed on the recording material layer. In an optical system used for the medium, the image sensor, for detecting the reflected laser light, is set up in the same medium side as the medium side into which the reproducing laser light emitted from a light source is irradiated.

Accordingly, in the reflected light reproducing type medium, the supporting substrate positioned at the medium surface side into which the reproducing laser light is irradiated, the recording material layer, and other optional layer(s) positioned nearer to the medium side into which the reproducing laser light is irradiated than the reflective film are each made of a light-transmitting material. It is unallowable that these members each substantially contain an element blocking the incident or reflective reproducing laser light. The supporting substrate is usually a rigid substrate made of glass or resin. The supporting substrate positioned at the medium surface side into which the reproducing laser light is irradiated is required to have a light-transmitting property.

In any case of the transmitted light reproducing type medium and the reflected light reproducing type medium, it is important that the hologram recording material layer has a high light transmittance of, for example, 50% or more at a wavelength of 405 nm. For example, in the case of considering a layer (100 μm in thickness) composed only of the matrix material (metal oxide material), it is preferred that the layer has a high light transmittance of 90% or more at a wavelength of 405 nm.

The hologram recording material layer obtained as above-mentioned has a high transmittance to a blue laser. Therefore, even if a thickness of the recording material layer is set to 100 μm, a recording medium having a light transmittance of 50% or more, preferably 55% or more at a wavelength of 405 nm is obtained when the medium is a transmitted light reproducing type medium; or a recording medium having a light reflectance of 25% or more, preferably 27.5% or more at a wavelength of 405 nm is obtained when the medium is a reflected light reproducing type medium. In order to attain holographic memory recording characteristics such that a high multiplicity is ensured, necessary is a recording material layer having a thickness of 100 μm or more, preferably 200 μm or more. According to the present invention, however, even if the thickness of the recording material layer is set to, for example, 1 mm, it is possible to ensure a light transmittance of 50% or more at a wavelength of 405 nm (when the medium is a transmitted light reproducing type medium), or a light reflectance of 25% or more at a wavelength of 405 nm (when the medium is a reflected light reproducing type medium).

When the above described hologram recording material layer is used, a hologram recording medium having a recording layer thickness of 100 μm or more, which is suitable for data storage, can be obtained. The hologram recording medium can be produced by forming the hologram recording material in a film form onto a substrate, or sandwiching the hologram recording material in a film form between substrates.

In a transmitted light reproducing type medium, it is preferred to use, for the substrate(s), a material transparent to a recording/reproducing wavelength, such as glass or resin. It is preferred to form an anti-reflection film against the recording/reproducing wavelength for preventing noises or give address signals and so on, onto the substrate surface at the side opposite to the layer of the hologram recording material. In order to prevent interface reflection, which results in noises, it is preferred that the refractive index of the hologram recording material and that of the substrate are substantially equal to each other. It is allowable to form, between the hologram recording material layer and the substrate, a refractive index adjusting layer comprising a resin material or oil material having a refractive index substantially equal to that of the recording material or the substrate. In order to keep the thickness of the hologram recording material layer between the substrates, a spacer suitable for the thickness between the substrates may be arranged. End faces of the recording material medium are preferably subjected to treatment for sealing the recording material.

About the reflected light reproducing type medium, it is preferred that the substrate positioned at the medium surface side into which a reproducing laser light is irradiated is made of a material transparent to a recording and reproducing wavelength, such as glass or resin. As the substrate positioned at the medium surface side opposite to the medium surface side into which a reproducing laser light is irradiated, a substrate having thereon a reflective film is used. Specifically, a reflective film made of, for example, Al, Ag, Au or an alloy made mainly of these metals and the like is formed on a surface of a rigid substrate (which is not required to have a light-transmitting property), such as glass or resin, by vapor deposition, sputtering, ion plating, or any other film-forming method, whereby a substrate having thereon the reflective film is obtained. A hologram recording material layer is provided so as to have a predetermined thickness on the surface of the reflective film of this substrate, and further a light-transmitting substrate is caused to adhere onto the surface of this recording material layer. An adhesive layer, a flattening layer and the like may be provided between the hologram recording material layer and the reflective film, and/or between the hologram recording material layer and the light-transmitting substrate. It is also unallowable that these optional layers hinder the transmission of the laser light. Others than this matter are the same as in the above-mentioned transmitted light reproducing type medium.

The hologram recording medium of the present invention can be preferably used not only in a system wherein record and reproduction are made using a green laser light but also in a system wherein record and reproduction are made using a blue laser light having a wavelength of 350 to 450 nm.

### EXAMPLES

The present invention will be specifically described by way of the following examples; however, the invention is not limited to the examples.

### Example 1

Dipheyldimethoxysilane and a titanium butoxide oligomer represented by the following structural formula illustrated below were used to produce a hologram recording material through steps described below according to a sol-gel process.

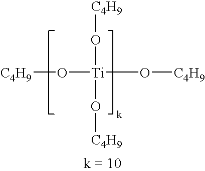

### (Synthesis of a Matrix Material)

Mixed were 7.9 g of diphenyldimethoxysilane and 7.2 g of the titanium butoxide oligomer (B-10, manufactured by Nippon Soda Co., Ltd.) to prepare a metal alkoxide mixed liquid, wherein the ratio by mole of Ti/Si was 1/1.

A solution composed of 1.0 mL of water, 0.3 mL of a 1 N aqueous solution of hydrochloric acid, and 7 mL of 1-methoxy-2-propanol was dropwise added to the metal alkoxide mixed liquid at a room temperature while the liquid was stirred. The resultant was continuously stirred for 2 hours to conduct hydrolysis and condensation reaction. The percentage of the metal alkoxide starting materials in the whole of the reaction solution was 67% by mass. In this way, a sol solution was obtained.

### (Photopolymerizable Compound)

To 100 parts by weight of polyethylene glycol diacrylate (M-245, manufactured by Toagosei Co., Ltd.) as a photopolymerizable compound were added 3 parts by weight of a photopolymerization initiator (IRG-907, manufactured by Ciba Specialty Chemicals K.K.) and 0.3 part by weight of thioxanthen-9-one as a photosensitizer to prepare a mixture containing the photopolymerizable compound.

### (Hologram Recording Material Solution)

The sol solution and the mixture containing the photopolymerizable compound were mixed with each other at a room temperature to set the ratio of the matrix material (as a nonvolatile component) and that of the photopolymerizable compound to 67 parts by weight and 33 parts by weight, respectively, to obtain a hologram recording material solution substantially transparent and colorless.

### (Hologram Recording Material)

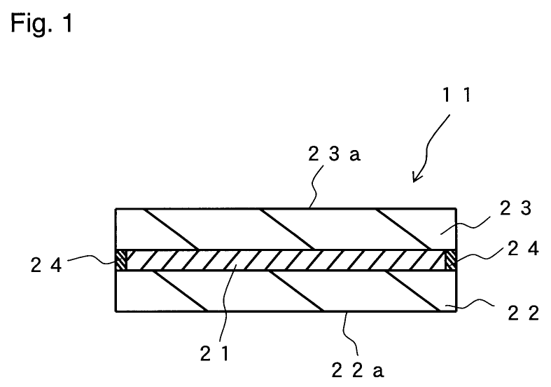

With reference to FIG. 1, which schematically illustrates a cross section of a hologram recording medium, explanation will be described.

A glass substrate (22) having a thickness of 1 mm and having one surface on which an anti-reflection film (22a) was formed was prepared. A spacer (24) having a predetermined thickness was put on a surface of the glass substrate (22) on which the anti-reflection film (22a) was not formed, and the hologram recording material solution obtained was applied onto the surface of the glass substrate (22). The resultant was dried at a room temperature for 1 hour, and then dried at 40 ° C. for 24 hours to volatilize the solvent. Through this drying step, the gelation (condensation reaction) of the metal oxide was advanced so as to yield a hologram recording material layer (21) having a dry film thickness of 400 μm wherein the metal oxide and the photopolymerizable compound were uniformly dispersed.

### (Hologram Recording Medium)

The hologram recording material layer (21) formed on the glass substrate (22) was covered with another glass substrate (23) having a thickness of 1 mm and having one surface on which an anti-reflection film (23a) was formed. At this time, the covering was carried out in such a manner that a surface of the glass substrate (23) on which the anti-reflection film (23a) was not formed would contact the surface of the hologram recording material layer (21). In this way, a hologram recording medium (11) was obtained which had a structure wherein the hologram recording material layer (21) was sandwiched between the two glass substrates (22) and (23).

### (Evaluation of Characteristics)

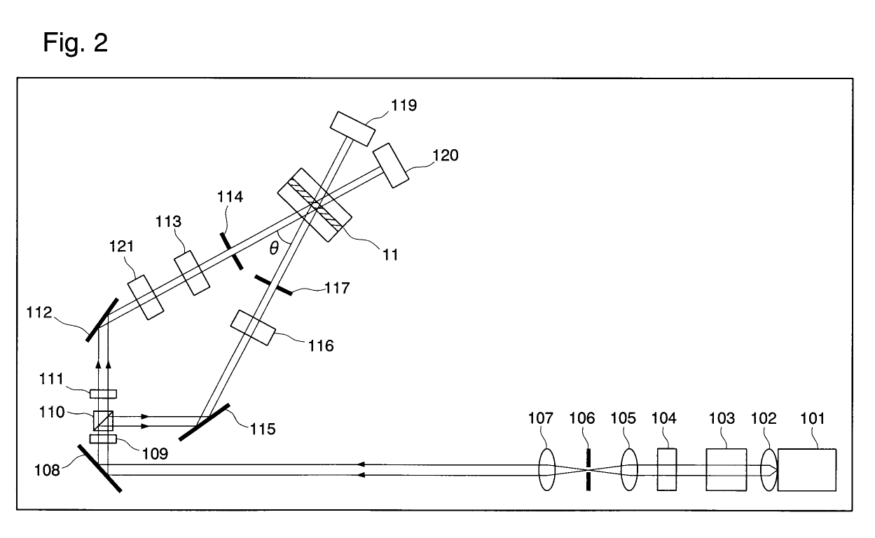

About the resultant hologram recording material sample, characteristics thereof were evaluated in a hologram recording optical system as illustrated in FIG. 2. The direction along which the paper surface on which FIG. 2 is drawn stretches is defined as a horizontal direction for convenience' sake.

In FIG. 2, the hologram recording medium sample (11) was set to make the recording material layer perpendicular to the horizontal direction.

In the hologram recording optical system illustrated in FIG. 2, a light source (101) for emitting a semiconductor laser (wavelength: 405 nm) in a single mode oscillation was used. Light emitted from this light source (101) was subjected to a spatial filtrating treatment by means of a beam rectifier (102), a light isolator (103), a shutter (104), a convex lens (105), a pinhole (106), and a convex lens (107), so as to be collimated, thereby enlarging the light into a beam diameter of about 10 mmφ. The enlarged beam was passed through a mirror (108) and a ½ wavelength plate (109) to take out 45° (45 degree) polarized light. The light was split into an S wave and a P wave (the ratio of S wave/P wave is 1/1) through a polarized beam splitter (110). The S wave obtained by the splitting was passed through a mirror (115), a polarizing filter (116), and an iris diaphragm (117) while a ½ wavelength plate (111) was used to convert the P wave obtained by the splitting to an S wave and then the S wave was passed through a mirror (112), a polarizing filter (113) and an iris diaphragm (114). In this way, the total incident angle θ of the two light fluxes irradiated into the hologram recording medium sample (11) was set to 37°, so as to record interference fringes of the two light fluxes in the sample (11).

The sample (11) was rotated in the horizontal direction to attain multiplexing (angle multiplexing; sample angle: −21° to +21°, angular interval: 3°) and further the sample (11) was rotated around an axis perpendicular to the surface of the sample 11 to attain multiplexing (peristrophic multiplexing; sample angle: 0 to 90°, angular interval: 10°), thereby recording a hologram. The multiplicity was 150. At the time of the recording, the sample was exposed to the light while the iris diaphragms (114) and (117) were each set into 4φ.

Details of this multiple recording will be described hereinafter. The sample (11) was rotated in the horizontal direction (around the axis perpendicular to the paper surface) from −21° to +21° at angular intervals of 3° to attain multiplexing. Thereafter, the sample (11) was rotated at 10° (i.e., 10° when it was viewed from the side into which the laser light was irradiated) around the axis perpendicular to the surface of the sample (11). The sample (11) was again rotated in the horizontal direction from −21° to +21° at angular intervals of 3° to attain multiplexing. This was repeated 10 times to rotate the sample (11) around the axis perpendicular to the surface of the sample (11) from 0° to 90°, thereby attaining multiple recording giving a multiplicity of 150.

A position where the angle of the surface of the sample (11) to a central line (not illustrated) for dividing the angle θ made by the two light fluxes into two equal parts was 90° was defined as a position where the angle in the horizontal rotation was ±0°. The axis perpendicular to the surface of the sample (11) is as follows: when the sample (11) is rectangular, the axis is a perpendicular axis passing at an intersection point of the two diagonal lines; and when the sample (11) is circular, the axis is a perpendicular axis passing at the center of the circle.

In order to react remaining unreacted components after the hologram recording, a sufficient quantity of light was irradiated by use of only one light fluxes. At the time of reproduction, with shading by the shutter (121), the iris diaphragm (117) was set into 3φ and only one light flux was irradiated. The sample (11) was continuously rotated into the horizontal direction from −23° to +23° and further rotated around the axis perpendicular to the surface of the sample (11) from 0° to 90° at angular intervals of 10°. In the individual angle positions, the diffraction efficiency was measured with a power meter (120). When a change in the volume (a recording shrinkage) or a change in the average refractive index of the recording material layer is not generated before and after the recording, the diffraction peak angle in the horizontal direction at the time of the recording is consistent with that at the time of the reproduction. Actually, however, a recording shrinkage or a change in the average refractive index is generated; therefore, the diffraction peak angle in the horizontal direction at the time of the reproduction is slightly different from the diffraction peak angle in the horizontal direction at the time of the recording. For this reason, at the time of the reproduction, the angle in the horizontal direction was continuously changed and then the diffraction efficiency was calculated from the peak intensity when a diffraction peak made its appearance. In FIG. 2, reference number (119) represents a power meter not used in this example.

At this time, a dynamic range M/# (the sum of the square roots of the diffraction efficiencies) was a high value of 17.8, which was a converted value corresponding to the case that the thickness of the hologram recording material layer was converted to 1 mm. A light transmittance of the medium (recording layer thickness: 400 μm) before the recording exposure to light (i.e., at the initial stage) was 71% at 405 nm. A fall in the light transmittance of the medium at 405 nm (i.e., the recording wavelength) after the recording was not observed.

At this time, a reduction ratio in the light transmittance on the basis of the glass substrates (22) and (23) each having the anti-reflection film was 0.6%. Specifically, with reference to FIG. 1, a laser light was irradiated into the sample (11) from the side of the substrate (22), so as to be transmitted toward the side of the substrate (23); in this case, 0.3% of the light was reflected on the interface between the air and the anti-reflection film (22a) by the presence of the anti-reflection film (22a), and 99.7% thereof was transmitted (absorption: 0%), and 0.3% of the transmitted light (that is, 99.7%) was reflected on the interface between the anti-reflection film (23a) of the substrate (23) and the air. As a result, 99.4% of the original laser light was transmitted.

The refractive index of the glass substrates (22) and (23) was substantially equal to that of the hologram recording material layer (21); therefore, reflection on the interface between the glass substrate (22) and the recording material layer (21) and reflection on the interface between the recording material layer (21) and the glass substrate (23) may be neglected.

### (Measurement of Particle Diameter of the Extracted Sol)

The hologram recording material layer was scratched away from the hologram recording medium sample (before said medium was exposed to the light for recording), so as to obtain 1,000 mg of the hologram recording material. Thereto was added 100 g of n-butyl alcohol, and the resultant was subjected to ultrasonic vibration with a device 2510J-DTH manufactured by Branson Co. at 25° C. for 1 hour followed by stirring at 25° C. for 9 hours. The extraction operation gave a sol solution.

The resultant sol solution was filtrated two times through syringe filters [disposable filter units 25HP045AN made of hydrophilic PTFE, manufactured by Toyo Roshi Kaisha, Ltd.; pore diameter: 0.45 μm], so as to yield a filtrated sol solution sample. In each of the two filtration operations, each of the syringe filters used was a virgin syringe filter.

A dynamic light scattering photometer (DLS-6500, manufactured by Otsuka Electronics Co., Ltd.) was used to measure the particle diameter distribution of sol particles in the filtrated sol solution sample. As a result, the average particle diameter of the sol particles in the sol solution sample was 20 nm.

### Example 2

### (Synthesis of a Matrix Material)

Mixed were 7.9 g of diphenyldimethoxysilane and 2.9 g of the titanium butoxide oligomer (B-10, manufactured by Nippon Soda Co., Ltd.) to prepare a metal alkoxide mixed liquid, wherein the ratio by mole of Ti/Si was 4/10.

A solution composed of 0.7 mL of water, 0.2 mL of a 1 N aqueous solution of hydrochloric acid, and 5 mL of 1-methoxy-2-propanol was dropwise added to the metal alkoxide mixed liquid at a room temperature while the liquid was stirred. The resultant was continuously stirred for 1 hour to conduct hydrolysis and condensation reaction. The percentage of the metal alkoxide starting materials in the whole of the reaction solution was 67% by mass. In this way, a sol solution was obtained.

A hologram recording material solution was prepared and a hologram recording medium was produced in the same manner as in Example 1 except that the resultant sol solution was used. The hologram recording material solution was substantially transparent and colorless.

About the resultant hologram recording medium sample, characteristics thereof were evaluated in the same manner as in Example 1. At this time, a dynamic range M/# was 12.3, which was a converted value corresponding to the case that the thickness of the hologram recording material layer was converted to 1 mm.

A light transmittance of the medium (recording layer thickness: 400 μm) before the recording exposure to light (i.e., at the initial stage) was 73% at 405 nm. A fall in the light transmittance of the medium at 405 nm (i.e., the recording wavelength) after the recording was not observed.

Moreover, the hologram recording medium sample was subjected to the same extraction operation as in Example 1, and then the particle diameter distribution of sol particles in the filtrated sol solution sample was measured. As a result, the average particle diameter of the sol particles was 7 nm.

### Comparative Example 1

A sol solution was obtained in the same manner as in Example 1 except that in the synthesis of the matrix material, 3.95 g of phenyltrimethoxysilane and 3.95 g of methyltriethoxysilane were used instead of 7.9 g of diphenyldimethoxysilane and the time for the hydrolysis, and condensation reaction was set to 10 hours.

A hologram recording material solution was prepared and a hologram recording medium was produced in the same manner as in Example 1 except that the resultant sol solution was used.

About the resultant hologram recording medium sample, characteristics thereof were evaluated in the same manner as in Example 1. At this time, a dynamic range M/# was 8.7, which was a converted value corresponding to the case that the thickness of the hologram recording material layer was converted to 1 mm. The value was a lower value than in Example 1.

A light transmittance of the medium (recording layer thickness: 400 μm) before the recording exposure to light (i.e., at the initial stage) was 48% at 405 nm, and was lower than the light transmittance in Example 1. After the recording, the light transmittance of the medium was 42% at 405 nm (i.e., the recording wavelength).

Moreover, the hologram recording medium sample was subjected to the same extraction operation as in Example 1, and then the particle diameter distribution of sol particles in the filtrated sol solution sample was measured. As a result, the average particle diameter of the sol particles was 150 nm.

In this comparative example, the average particle diameter of the sol particles became larger than in Example 1 by using phenyltrimethoxysilane and methyltriethoxysilane, which are higher in reactivity, instead of diphenyldimethoxysilane, and further by making the time for the hydrolysis and condensation reaction longer.

The above-mentioned example is about the transmitted light reproducing type medium having a light transmittance of 50% or more at a wavelength of 405 nm; however, it is evident that by use of a similar hologram recording material layer, a reflected light reproducing type medium having a light reflectance of 25% or more at a wavelength of 405 nm can be also produced.

What is claimed is:

1. A hologram recording medium comprising at least a hologram recording layer,
wherein the hologram recording layer contains a metal oxide matrix comprising metal oxide fine particles, and a photopolymerizable compound, the metal oxide fine particles comprise metal oxide fine particles containing Ti as a metallic element, and
at the time of subjecting the hologram recording layer before exposure to light for recording to an extraction operation in h-butyl alcohol having a mass 100 times the mass (W) of said recording layer under the following conditions:
ultrasonic vibration at 25° C. for 1 hour followed by stirring at 25° C. for 9 hours, thereby yielding a sol solution;
filtrating the sol solution two times through syringe filters having a pore diameter of 0.45 μm;
measuring particle diameter distribution of sol particles in the filtrated sol solution by a dynamic light scattering method; and obtaining an average particle diameter thereof, the average particle diameter of the sol particles is in the range of 5 nm or more and 50 nm or less.

2. The hologram recording medium according to claim 1, wherein a dry mass (W_{D}) of the filtrated sol solution is 80% or more of the mass (W) of the recording layer before the extraction operation.

3. The hologram recording medium according to claim 1, wherein the metal oxide matrix is a matrix prepared from a titanium compound having at least one hydrolyzable group.

4. The hologram recording medium according to claim 1, wherein the metal oxide matrix is a matrix prepared from a titanium compound having at least one hydrolyzable group and a silicon compound having at least one hydrolyzable group.

5. The hologram recording medium according to claim 1, further comprising a photopolymerization initiator.

6. The hologram recording medium according to claim 1, wherein the hologram recording layer has a thickness of at least 100 μm.

7. The hologram recording medium according to claim 1, wherein said hologram recording medium has a light transmittance is 50% or more at a wavelength of 405 nm, or a light reflectance is 25% or more at a wavelength of 405 nm.

8. The hologram recording medium according to claim 1, wherein record/reproduction of said hologram recording medium are made using a laser light having a wavelength of 350 to 450 nm.
